(19) United States
(12) Patent Application Publication
(10) Pub. No.: US 2010/0026403 A1
(43) Pub. Date: Feb. 4, 2010

(54) SELECTABLE DRIVE STRENGTH HIGH FREQUENCY CRYSTAL OSCILLATOR CIRCUIT

(75) Inventors: Parvinder Rana, Ambala (IN); Rajesh Yadav, Ahmedabad (IN)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 12/181,394

(22) Filed: Jul. 29, 2008

(51) Int. Cl. H03B 5/30; H03B 5/32

(52) U.S. Cl. 331/116 R; 331/158

(57) ABSTRACT

A method, system, and apparatus to a selectable drive strength high frequency crystal oscillator circuit are disclosed. In one embodiment, a system includes a crystal oscillator circuit to generate a signal with a specified frequency value, and a programmable amplifier circuit containing a plurality of programmable inverting amplifiers, and wherein certain ones of a plurality of inverting amplifiers are operated to change a gain and/or a bandwidth of the signal according to the specified frequency value of the crystal oscillator circuit. The system may include further comprising a resistor circuit coupled in parallel to the programmable amplifier circuit to set an operating point of the programmable amplifier circuit.

### FIELD OF TECHNOLOGY

This disclosure relates generally to an enterprise method, a technical field of software and/or hardware technology and, in one example embodiment, to a selectable drive strength high frequency crystal oscillator circuit

### BACKGROUND

A device of an integrated circuit may operate at a specified frequency. The specified frequency may be controlled by a crystal oscillator circuit (e.g., an electronic circuit that uses a mechanical resonance of a vibrating crystal of a piezoelectric material to create a signal with the specified frequency). The crystal oscillator circuit may use an amplifier (e.g., a device that changes an amplitude of the signal) to supply gain (e.g., to increase a power value, to increase a ratio of an output power to an input power) of the signal of a crystal oscillator. The integrated circuit may employ the crystal oscillator to operate at a variety of frequencies. The amplifier may be limited to a particular range of frequencies. Consequently, the integrated circuit may use a set of amplifiers to provide a different gain at a different time instant during an operation of the integrated circuit. The set of amplifiers may occupy an area of space within the integrated circuit. Thus, the use of the set of amplifiers may increase the size of the integrated circuit. Furthermore, the set of integrated amplifiers may increase the complexity of a design of the integrated circuit and/or may increase the consumption of power of the integrated circuit.

### SUMMARY

A method, system, and apparatus to a selectable drive strength high frequency crystal oscillator circuit are disclosed. In one aspect, a system includes a crystal oscillator circuit to generate a signal with a specified frequency value, and a programmable amplifier circuit containing a plurality of programmable inverting amplifiers. Certain ones of a plurality of inverting amplifiers may be operated to change an at least one of a gain and a bandwidth value of the output signal according to the specified frequency value of the crystal oscillator circuit.

The system may include a resistor circuit coupled in parallel to the programmable amplifier circuit to set an operating point of the programmable amplifier circuit. The system may also include a capacitor circuit that may be included load capacitors of a specified value to provide a specified phase shift to the signal. In addition, the system may include a buffer circuit associated with the programmable amplifier to prevent integrated circuit from interfering with an operation of the crystal oscillator circuit, the programmable amplifier circuit, the resistor circuit and/or the capacitor circuit.

The system may include a control module (e.g., may determine a logic state of the selection pins) to determine the gain value and/or the bandwidth value of an output signal of the programmable amplifier circuit according to the specified frequency value of the crystal oscillator circuit. The system may also include an input macro circuit to determine the specified frequency value of the crystal oscillator circuit. In addition, the system may include selection pins to couple a logic block circuit (e.g., may determine the gain and/or the bandwidth value of the output signal of the programmable amplifier circuit according to the logic state of the selection pins) with both the control module and/or a programmable power amplifier.

The programmable amplifier circuit may include an on-state inverting amplifier coupled in parallel with the programmable inverting amplifiers coupled in parallel. The on-state inverting amplifier may include a p-type arm that may include a pair of p-type semiconductors and/or a voltage source coupled in series and an n-type arm that may include a pair of n-type semiconductors and/or a ground coupled in series. The on-state inverting amplifier may be coupled with a signal transmission line from the crystal oscillator circuit, an output signal transmission line and/or the control module. The on-state inverting amplifier may be in an active state of operation if a crystal oscillator is in the active state of operation. The on-state inverting amplifier may be in an inactive state of operation if the crystal oscillator is in the inactive state of operation.

A programmable inverting amplifier may include a p-type semiconductor coupled in parallel with an other p-type semiconductor of the on-state inverting amplifier and an n-type semiconductor coupled in parallel with an other n-type semiconductor of the on-state inverting amplifier. A mode of operation of the programmable inverting amplifier may be determined by the logic block circuit according to the logic state of the selection pins. The logic block circuit may determine the gain and the bandwidth value of the output signal of the programmable amplifier circuit according to the mode of operation of the programmable inverting amplifiers.

The programmable inverting amplifier may include a p-type arm including two p-type semiconductors and the voltage source coupled in series and an n-type arm may include of two n-type semiconductors and the ground coupled in series. The p-type arm may be coupled with the output the output signal of the programmable amplifier circuit and the n-type arm is coupled with the signal transmission line from the crystal oscillator circuit. The resistor circuit may be located within the programmable amplifier circuit. The programmable amplifier circuit may generate the gain and/or the bandwidth value of the output signal according to a required power value of a device of the integrated circuit associated with the programmable amplifier circuit.

In another aspect, a method includes generating a frequency signal using a crystal oscillator circuit (e.g., uses the mechanical resonance of a vibrating crystal of piezoelectric material to create an electrical signal with a very precise frequency), and configuring a programmable amplifier circuit associated with the crystal oscillator circuit to contain a plurality of programmable inverting amplifiers. Certain ones of the plurality of programmable inverting amplifiers are operated to change at least one of a gain value and a bandwidth value of a signal of the programmable amplifier circuit according a frequency value of the crystal oscillator circuit.

The method may include configuring a resistor circuit coupled in parallel to the programmable amplifier circuit to set an operating point of the programmable amplifier circuit. The method may configure a capacitor circuit that may include load capacitors of a specified value to provide a specified phase shift to a signal. The method may also configure a buffer circuit associated with the programmable amplifier circuit value to an integrated circuit and to prevent the integrated circuit from interfering with an operation of the crystal oscillator circuit, the programmable amplifier circuit, the resistor circuit and/or the capacitor circuit.

The method may include configuring a control module to determine the gain and/or the bandwidth value of the output signal of the programmable amplifier circuit according to a specified frequency value of the crystal oscillator circuit. The method may configure an input macro circuit to determine the specified frequency value of the crystal oscillator circuit according to a command signal of the control module. The control module may be used to decrease a power use of an integrated circuit associated with the programmable amplifier by setting a specified number of inverting amplifiers in an active state. The method may include using selection pins to couple a logic block circuit with both the control module and a programmable power amplifier with the plurality of selection pins. The method may determine a logic state of the selection pins. The method may determine the gain value and/or the bandwidth value of the output signal of the programmable amplifier circuit according to the logic state of the selection pins.

The method may include configuring the programmable amplifier circuit with an on-state inverting amplifier coupled in parallel with the programmable inverting amplifiers coupled in parallel. The method may configure the on-state inverting amplifier with a p-type arm may include a pair of p-type semiconductors and a voltage source coupled in series and an n-type arm that may include a pair of n-type semiconductors and/or a ground coupled in series. The method may couple the on-state inverting amplifier with a signal transmission line from the crystal oscillator circuit, an output signal transmission line and/or the control module. The method may configure the on-state inverting amplifier to be in an active state of operation if the crystal oscillator circuit may be in the active state of operation.

The method may configure the on-state inverting amplifier to be in an inactive state of operation if the crystal oscillator may be in the inactive state of operation. The method may include configuring a programmable inverting amplifier with a p-type semiconductor coupled in parallel with an other p-type semiconductor of the on-state inverting amplifier and an n-type semiconductor coupled in parallel with an other n-type semiconductor of the on-state inverting amplifier. The method may include determining a mode of operation of the programmable inverting amplifier according to the logic state of certain ones of the selection pins. The method may include determining the gain and/or the bandwidth value of the output signal of the programmable amplifier circuit according to the mode of operation of certain ones of the programmable inverting amplifiers.

The method may include configuring the programmable inverting amplifier with a p-type arm may include two p-type semiconductors and the voltage source coupled in series and an n-type arm that may include two n-type semiconductors and/or the ground coupled in series. The method may couple the p-type arm with the output the output signal of the programmable amplifier circuit. The method may also couple the n-type arm with the signal transmission line from the crystal oscillator circuit. The method may include configuring the programmable amplifier circuit to generate the gain and/or the bandwidth value of the output signal according to a required power value of a device of the integrated circuit associated with the crystal oscillator circuit.

In yet another aspect, a system includes a vibrating crystal of a piezoelectric material to create an electrical signal, an amplifier to change a gain value of the electrical signal and configured with a plurality of inverting amplifier arms in parallel comprising a programmable inverting amplifier coupled with a switch, and an output control module coupled to the amplifier to control the operation of certain ones of a plurality of amplifier arms according to a frequency of the electrical signal of the vibrating crystal.

The control module may activate the amplifier arms according to a power requirement of a device associated with the vibrating crystal. The system may include capacitor to provide a specified phase shift to the electrical signal.

The methods, systems, and apparatuses disclosed herein may be implemented in any means for achieving various aspects, and may be executed in a form of a machine-readable medium embodying a set of instructions that, when executed by a machine, cause the machine to perform any of the operations disclosed herein. Other features will be apparent from the accompanying drawings and from the detailed description that follows.

### BRIEF DESCRIPTION OF THE DRAWINGS

Example embodiments are illustrated by way of example and not limitation in the figures of the accompanying drawings, in which like references indicate similar elements and in which:

FIG. 1 is a system view of a selectable gain circuit coupled with an integrated circuit, according to one embodiment.

FIG. 2 is a systematic view illustrating a crystal oscillator 108 coupled with a programmable amplifier circuit 112 to transmit a signal to a buffer circuit, according to one embodiment.

FIG. 3 is a system view illustrating a gain control for the integrated circuit using switches that may be controlled by using a logic block circuit, according to one embodiment.

FIG. 4 is a system view illustrating a constant gain configuration for the integrated circuit through the switches that may keep one of an inverting amplifier always on, according to one embodiment.

FIG. 5 is a schematic view illustrating an oscillator macros connection 550, according to one embodiment.

FIG. 6 is a block diagram illustrating a logic block that includes a selection pins, according to one embodiment.

FIG. 7 is a table view illustrating a truth table of configuration of switches, according to one embodiment.

FIG. 8 is a diagrammatic view illustrating a programmable inverting amplifiers 800 coupled with an on-state inverting amplifier 802, according to one embodiment.

FIG. 9 is a diagrammatic view illustrating a different configuration of the programmable inverting amplifier 900 coupled with the on-state inverting amplifier, according to one embodiment.

FIG. 10A is a process flow of generating a frequency signal using a crystal oscillator circuit, according to one embodiment.

FIG. 10B is a continuation of process flow of FIG. 10A, illustrating additional operations, according to one embodiment.

FIG. 10C is a continuation of process flow of FIG. 10B, illustrating additional operations, according to one embodiment.

Other features of the present embodiments will be apparent from the accompanying drawings and from the detailed description that follows.

### DETAILED DESCRIPTION

A method, system, and apparatus to a selectable drive strength high frequency crystal oscillator circuit are disclosed. Although the present embodiments have been described with reference to specific example embodiments, it will be evident that various modifications and changes may be made to these embodiments without departing from the broader spirit and scope of the various embodiments.

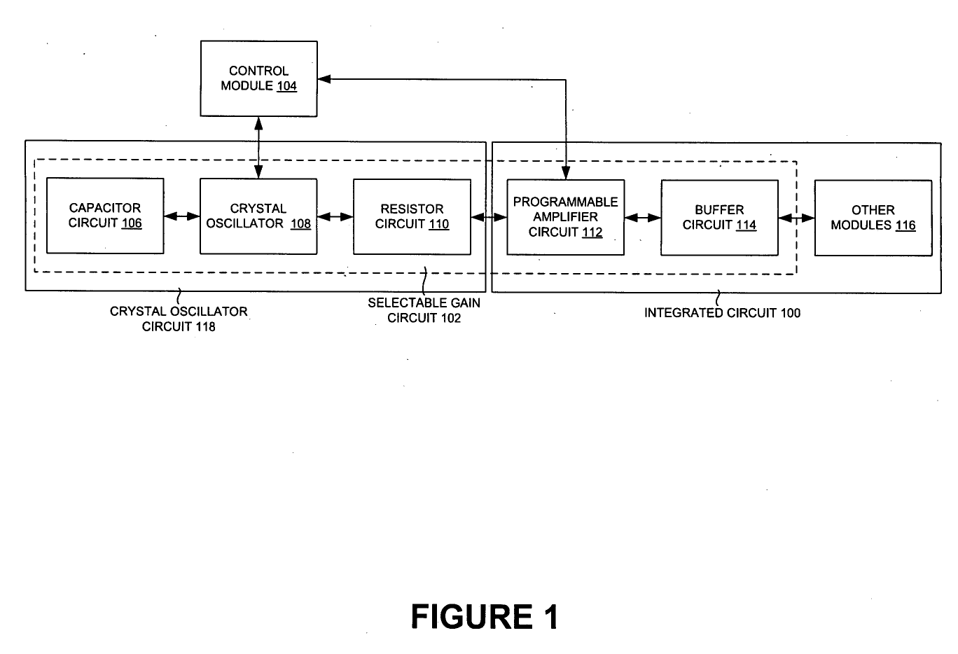

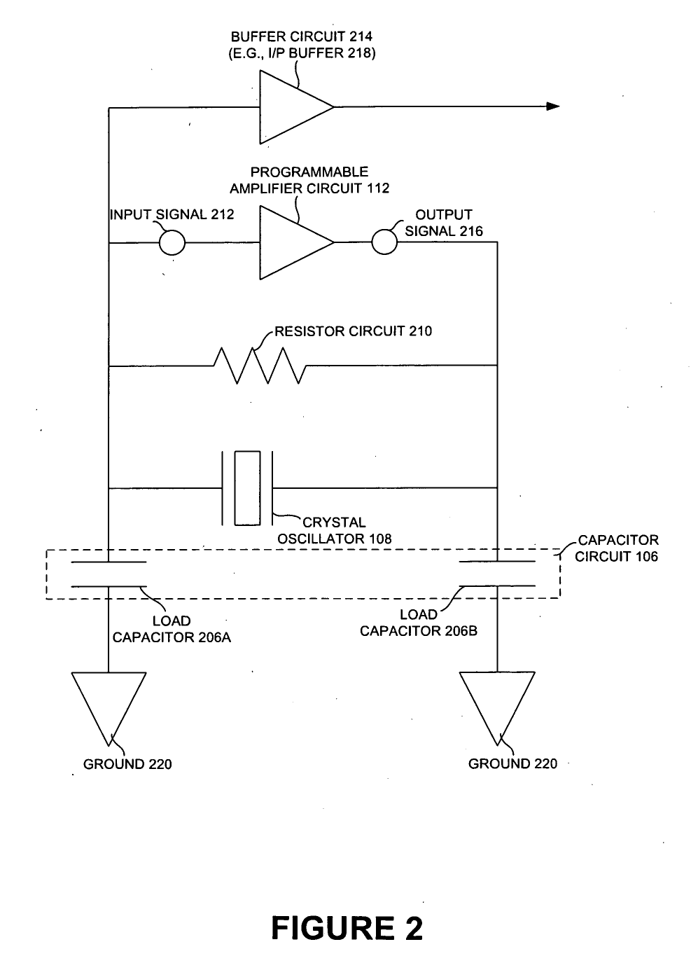

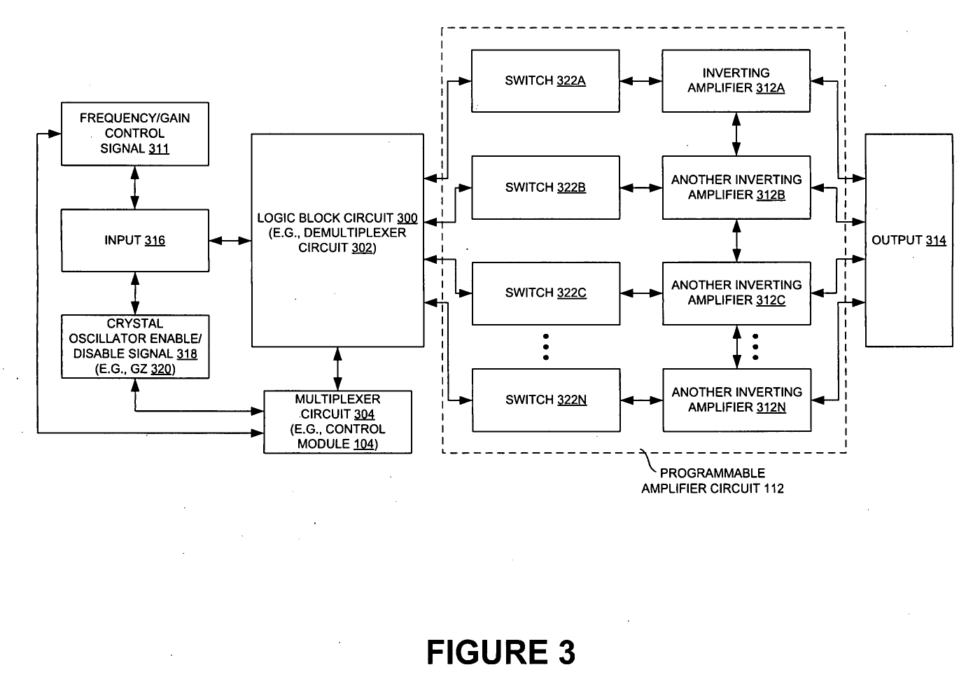

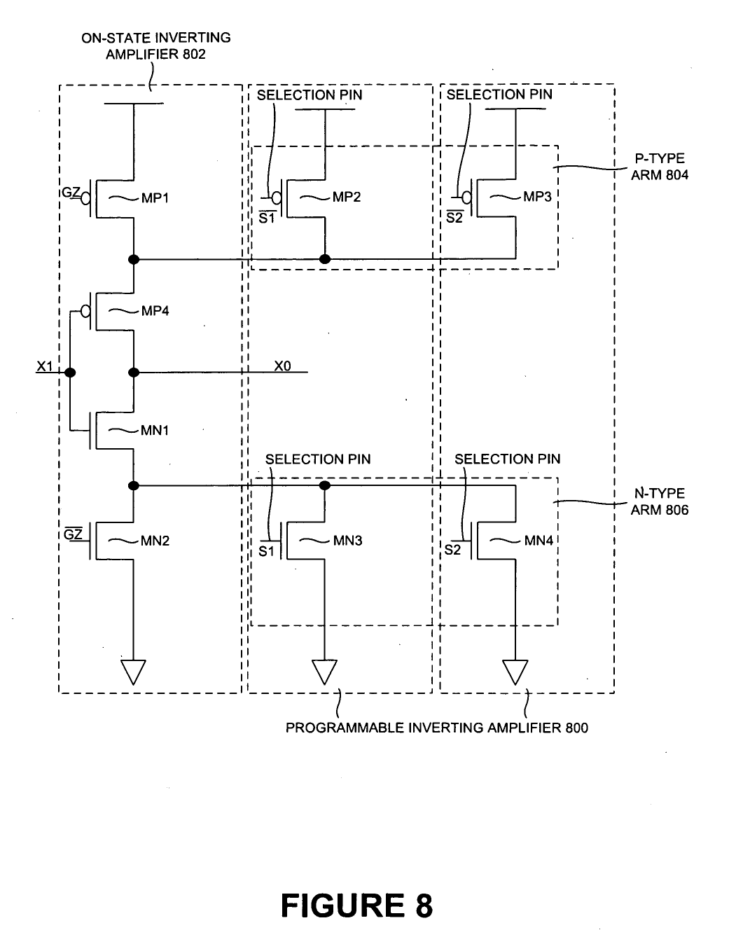

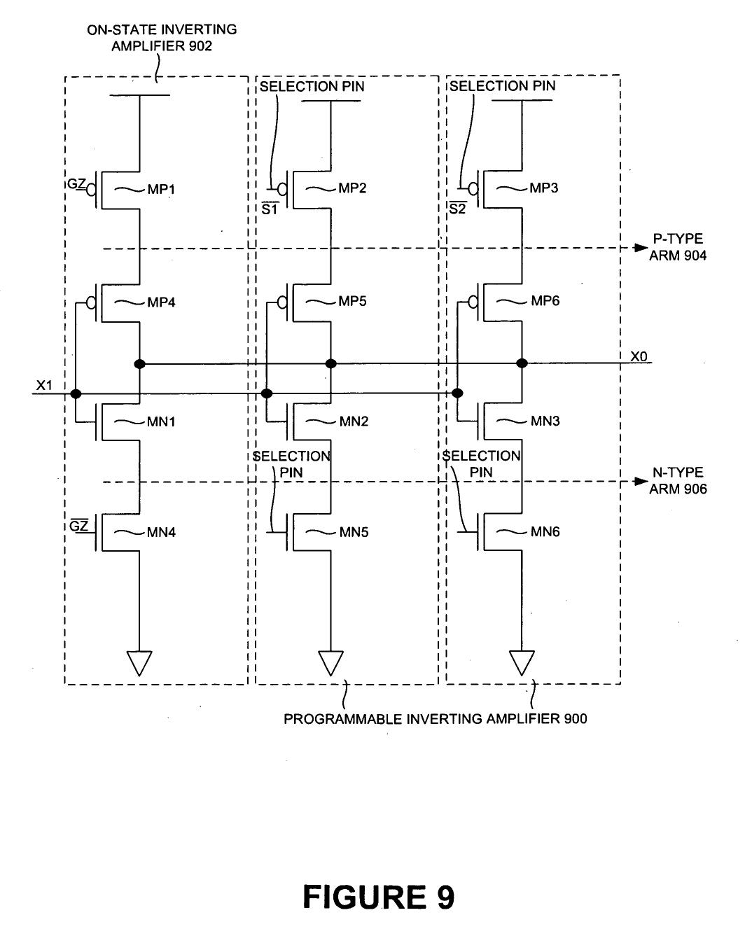

In one embodiment, a system includes a crystal oscillator circuit (e.g., the crystal oscillator circuit 118 of FIG. 1) to generate a signal (e.g., may be the input signal 212 of FIG. 2) with a specified frequency value (e.g., from a range of frequency values and range of gain), and a programmable amplifier circuit (e.g., the programmable amplifier circuit 112 of FIG. 1) containing a programmable inverting amplifiers (e.g., the programmable inverting amplifiers 800 and 900 of FIG. 8 and 9), and the certain ones of a inverting amplifiers (e.g., the inverting amplifiers 312A-N of FIG. 3) are operated to change at least one of a gain and a bandwidth of the signal according to the specified frequency value (e.g., from a range of frequency signals) of the crystal oscillator circuit 118.

In another embodiment, a method includes generating a frequency signal using a crystal oscillator circuit (e.g., the crystal oscillator circuit 118 of FIG. 1), and configuring a programmable amplifier circuit (e.g., the programmable amplifier circuit 112 of FIG. 1) associated with the crystal oscillator circuit 18 to contain a programmable inverting amplifiers (e.g., the programmable inverting amplifiers 800 and 900 of FIG. 8 and 9), and the certain ones of programmable inverting amplifiers 800/900 are operated to change at least one of a gain and a bandwidth of the signal of the programmable amplifier circuit according a frequency value of a crystal oscillator circuit (e.g., the crystal oscillator circuit 118 of FIG. 1).

In yet another embodiment, a system includes a vibrating crystal of a piezoelectric material to create an electrical signal, an amplifier to change a gain value of the electrical signal and configured with an inverting amplifier arms (e.g., may be the p-type arm, and the n-type arm) in parallel including a programmable inverting amplifier (e.g., the programmable inverting amplifiers 800 and 900 of FIG. 8 and 9) coupled with a switch (e.g., the switch 322A-N of FIG. 3), and an output control module (e.g., the control module 104 of FIG. 1) coupled to the amplifier to control the operation of certain ones of the amplifier arms according to a frequency of the electrical signal of the vibrating crystal.

FIG. 1 is a system view of a selectable gain circuit (e.g., the selectable gain circuit 102 of FIG. 1) coupled with an integrated circuit (e.g., the integrated circuit 100 of FIG. 1), according to one embodiment. Particularly, FIG. 1 illustrates an integrated circuit 100, a selectable gain circuit 102, a control module 104, a capacitor circuit 106, a crystal oscillator 108, a resistor circuit 110, a programmable amplifier circuit 112, a buffer circuit 114, other modules 116, and a crystal oscillator circuit 118, according to one embodiment.

The integrated circuit 100 (e.g., known as IC, microcircuit, microchip, chip, etc.) may be a miniaturized electronic circuit (e.g., may include semiconductor devices, passive components, etc.) that may be made on the surface of a thin substrate of semiconductor material (e.g., the programmable amplifier circuit 112, the buffer circuit 114, etc.) and may require a clock (e.g., derived from the frequency of the crystal circuit). The selectable gain circuit 102 may be a circuit that may provide a suitable gain for a specified frequency value based on the requirement of the IC.

The control module 104 may determine the gain and/or the bandwidth value of the output signal of the programmable amplifier circuit 112 according to the specified frequency value of the crystal oscillator circuit 118. The capacitor circuit 106 (e.g., a load capacitors of a specified value) may be the electrical and/or electronic device that may charge and discharge the circuits to provide phase shift (e.g., may be change in phase of a periodic signal with respect to another periodic signal and/or reference signal) to the signal.

The crystal oscillator 108 may be a part of a circuit that uses the mechanical resonance of a vibrating crystal (e.g., the piezoelectric material, etc.) to create the electrical signal with a very precise frequency (e.g., from a range of frequencies) to provide stable frequency (e.g., may be used in quartz wristwatches). The resistor circuit 110 may be an electrical and/or electronic component that may oppose the flow of an electric current by producing a voltage drop between its terminals in proportion to the current that may provide fixed operating point (e.g., may be a DC voltage and/or current, when applied to a device, causes it to operate in a certain desired criteria).

The programmable amplifier circuit 112 (e.g., an inverter amplifier, etc.) may be a device used to change and/or increase the gain and/or the bandwidth of the signal. (e.g., may be the voltage and/or current.). The buffer circuit 114 may be the buffer amplifier (e.g., voltage buffer, current buffer, input buffer, output buffer, etc.) that may be used to prevent the integrated circuit 100 (e.g., microcontroller, phase locked loop devices, etc.) from interfering with an operation of the crystal oscillator circuit 118. The other modules 116 may be semiconductor device (e.g., microcontroller, microprocessor, phase locked loop device, etc.) that may be connected to output of crystal oscillator device. The crystal oscillator circuit 118 may generate the signal (e.g., with variable gain based on requirement) that may be of specified frequency (e.g., from a range of frequencies).

In example embodiment, the selectable gain circuit 102 may be associated with the crystal oscillator circuit 118. The crystal oscillator circuit 118 may include the capacitor circuit 106, the crystal oscillator 108, and the resistor circuit 110. The crystal oscillator 108 may operate with the control module 104. The integrated circuit 100 may include the programmable amplifier circuit 112, the buffer circuit 114 may be coupled with the crystal oscillator circuit 118. The integrated circuit 100 may include the other modules 116 may be coupled with the crystal oscillator circuit 118. Once the oscillations have started, the control of the programmable amplifier circuit 112 may be changed to lower the power consumption of the circuit (e.g., the integrated circuit 100).

In one embodiment, the crystal oscillator circuit 118 may generate the signal with the specified frequency value. The programmable amplifier circuit 112 may include the programmable inverting amplifiers 800. The resistor circuit 110 may be coupled in parallel to the programmable amplifier circuit 112 to determine the operating point of the programmable amplifier circuit 112. The capacitor circuit 106 may include load capacitors 206A-B of the specified value to provide the specified phase shift to the signal. The buffer circuit 114 may be associated with the programmable amplifier circuit 112 to prevent the integrated circuit 100 from interfering with the operation of the crystal oscillator circuit 118, the programmable amplifier circuit 112, the resistor circuit 110 and the capacitor circuit 106.

The control module 104 may determine the gain and/or the bandwidth value of the output signal 314 of the programmable amplifier circuit 112 according to the specified frequency value of the crystal oscillator circuit 118. The resistor circuit 110 may be located within the programmable amplifier circuit 112. The programmable amplifier circuit 112 may generate the gain and/or the bandwidth value of the output signal 314 according to the required power value of the device of the integrated circuit 100 associated with the programmable amplifier circuit 112. The frequency signal may be generated using the crystal oscillator 108. The programmable amplifier circuit 112 associated with the crystal oscillator 108 may be configured to programmable inverting amplifiers 800. The resistor circuit 110 coupled in parallel to the programmable amplifier circuit 112 may be configured to determine the operating point of the programmable amplifier circuit 112. The resistor circuit 110 may also modify the behavior of alternating current within a system according to its resistance value. The capacitor circuit 106 including the load capacitors 206A-B of the specified value may provide the specified phase shift to the signal.

The buffer circuit 114 associated with the programmable amplifier circuit 112 may be configured to prevent the integrated circuit 100 from interfering with the operation of the crystal oscillator 108, the programmable amplifier circuit 112, the resistor circuit 110 and the capacitor circuit 106. The control module 104 may be configured to determine the gain and/or the bandwidth value of the output signal 314 of the programmable amplifier circuit 112 according to the specified frequency value of the crystal oscillator circuit 118. The gain and/or the bandwidth value of the output signal 314 of the programmable amplifier circuit 112 may be determined according to the logic state of certain ones of the selection pins. The programmable amplifier circuit 112 with the on-state inverting amplifier 802 coupled in parallel with the programmable inverting amplifiers 800 coupled in parallel may be configured.

The programmable amplifier circuit 112 may be configured to generate the gain and/or the amplitude value of the output signal 314 according to the required power value of the device of the integrated circuit 100 associated with the crystal oscillator 108. The vibrating crystal of the piezoelectric material may create the electrical signal. The amplifier may change the gain value of the electrical signal and configured with the inverting amplifier arms in parallel comprising the programmable inverting amplifier 800 coupled with the switch 322A-N. The output control module may be coupled to the amplifier to control the operation of certain ones of the amplifier arms according to the frequency of the electrical signal of the vibrating crystal. The control module 104 may activate amplifier arms according to the power requirement of the device associated with the vibrating crystal. The capacitor may provide the specified phase shift to the electrical signal.

FIG. 2 is a systematic view illustrating the crystal oscillator 108 coupled with the programmable amplifier circuit 112 to transmit a signal to a buffer circuit (e.g., the buffer circuit 114 of FIG. 1), according to one embodiment. Particularly, FIG. 2 illustrates the capacitor circuit 106, the crystal oscillator 108, the programmable amplifier circuit 112, a load capacitor 206A-B, a resistor circuit 210 (e.g., the R bits 220), an input signal 212, a buffer circuit 214 (e.g., the i/p buffer 218), an output signal 216, and a ground 220, according to one embodiment.

The load capacitor 206A-B may be associated with the capacitor circuit 106 that may provide necessary phase shift (e.g., may be a change in phase of a periodic signal with respect to another periodic signal or reference signal) to the signal. The resistor circuit 210 (e.g., R bits 220) may be associated with 110 that may provide fixed operating point (e.g., may be a DC voltage and/or current which, when applied to a device, causes it to operate in a certain desired fashion.) which may decide amplification of signal.

The input signal 212 may be signal (e.g., sinusoidal, square, etc.) that may be generated by crystal oscillator 108 (e.g., may act as a perfect band pass filter) for the integrated circuit 100. The buffer circuit 214 (e.g., I/P buffer 218) may translate signals (e.g., may be input signal 212 and/or output signal 216 of FIG. 2) to core level signals (e.g., the square wave signals). The output signal 216 may be an output signal (e.g., voltage, frequency, etc.) of the programmable amplifier circuit 112 (e.g., may be the inverting amplifier, etc.). The ground 220 may be a current return path through the earth to the low potential (e.g., voltage, etc.) side of an energy source.

In example embodiment, the crystal oscillator 108 may be coupled with the programmable amplifier circuit 112, and the resistor circuit 210 (e.g., R bits 220). The programmable amplifier circuit 112 may convert the input signal 212 to the output signal 216 that may be transmitted to the buffer circuit 214 (e.g., the i/p buffer 218). The capacitor circuit 106 associated with the load capacitors 206A-B may be coupled with the ground 220.

FIG. 3 is a system view illustrating a gain control for the integrated circuit using switches that may be controlled by using the logic block circuit 300, according to one embodiment. Particularly, FIG. 3 illustrates the programmable amplifier circuit 112, a logic block circuit 300 (e.g., the demultiplexer circuit 302), a multiplexer circuit 304 (e.g., the control module 104), a frequency/gain control signal 311, an inverting amplifier 312A-N, an output 314, an input 316, a crystal oscillator enable/disable signal 318 (e.g., GZ 320), and a switch 322A-N, according to one embodiment.

The logic block circuit 300 (e.g., a demultiplexer circuit 302) may determine the gain and/or the bandwidth value of the output signal 314 of the programmable amplifier circuit 112 according to the mode of operation of programmable inverting amplifier through the switches 322A-N. The multiplexer circuit 304 (e.g., the control module 104) may be a device that may select input (e.g., may be analog and/or digital signals) and/or output signals into a single line (e.g., in order to control the logic block circuit 300) (e.g., as a control signal). The frequency/gain control signal 311 may be associated with the control module 104 that may determine the gain, the bandwidth and/or the frequency value of the output signal 314 of the programmable amplifier circuit 112 according to the specified frequency value of the crystal oscillator circuit 118. The inverting amplifier 312A-N (e.g., may be constructed using the MOSFET's) may be associated with the programmable amplifier circuit 112 which may invert and/or amplifies the signal (e.g., current, voltage, frequency, etc.).

The output 314 may be an output signal (e.g., may be the frequency signal) obtained from respective inverting amplifier which may depend on logic states of the logic block circuit 300. The input 316 may be the input signal (e.g., may be the frequency signal) that may be generated from the crystal oscillator enable/disable signal 318. The crystal oscillator enable/disable signal 318 (e.g., the GZ 320) may be the signal which may be used to select oscillation mode and/or disable mode. The switch 322A-N (e.g., gate, etc.) may be a device (e.g., may be mechanical, electrical, etc.) used to form (e.g., make) and/or break the circuit (e.g., a logic block, an inverting amplifier, etc.). Once the oscillations have started, the control of the programmable amplifier circuit 112 may be changed to lower the power consumption of the circuit (e.g., the integrated circuit 100).

In example embodiment, the logic block circuit 300 (e.g., the demultiplexer circuit 302) may be coupled with the multiplexer circuit 304 (e.g., the control module 104 and as a control signal to the logic block circuit 300), and the programmable amplifier circuit 112. The programmable amplifier circuit 112 may include the switches 322A-N that may be coupled with the inverting amplifier 312, and the another inverting amplifier 312B-N in parallel to determine the gain and/or the amplitude value of the output signal 314. The input 316 obtained from the crystal oscillator enable/disable signal 318 (e.g., GZ 320) and may be controlled by frequency/gain control signal 311 associated with multiplexer circuit 304 (e.g., the control module 104) that may be coupled with the logic block circuit (e.g., the logic block circuit 300).

In one embodiment, the inverting amplifiers 312A-N may be operated to change the gain and/or the bandwidth value of the output signal 314 according to the specified frequency value of the crystal oscillator circuit 118. The logic block circuit 300 may determine the gain and/or the bandwidth value of the output signal 314 of the programmable amplifier circuit 112 according to the logic state of certain ones of the selection pins. The programmable inverting amplifier 800 may include the p-type semiconductor coupled in parallel with the other p-type semiconductor of the on-state inverting amplifier 802 and the n-type semiconductor coupled in parallel with the other n-type semiconductor of the on-state inverting amplifier 802. The mode of operation of the programmable inverting amplifier 800 may be determined by the logic block circuit 300 according to the logic state of certain ones of the selection pins. The logic block circuit 300 may determine the gain and/or the bandwidth value of the output signal 314 of the programmable amplifier circuit 112 according to the mode of operation of programmable inverting amplifiers 800. The programmable inverting amplifier 800 may include the p-type arm 804 that includes two p-type semiconductors and the voltage source coupled in series and the n-type arm 806 includes two n-type semiconductors and the ground 220 coupled in series.

The p-type arm 804 may be coupled with the output signal 314 of the programmable amplifier circuit 112 and the n-type arm 806 may be coupled with the signal transmission line from the crystal oscillator circuit 118. The programmable inverting amplifiers 800 may operate to change the gain and/or the bandwidth value output signal of the programmable amplifier circuit 112 according a frequency value of a crystal oscillator circuit 118. The programmable inverting amplifier 800 may be configured with the p-type semiconductor coupled in parallel with the other p-type semiconductor of the on-state inverting amplifier 802 and the n-type semiconductor coupled in parallel with the other n-type semiconductor of the on-state inverting amplifier 802.

The mode of operation of the programmable inverting amplifier 800 may be determined according to the logic state of certain ones of the selection pins. The gain and/or the frequency value of the output signal 314 of the programmable amplifier circuit 112 may be determined according to the mode of operation of programmable inverting amplifiers 800. The programmable inverting amplifier 800 may be configured with the p-type arm 804 may include two p-type semiconductors and the voltage source coupled in series and the n-type arm 806 may include two n-type semiconductors and the ground 220 coupled in series.

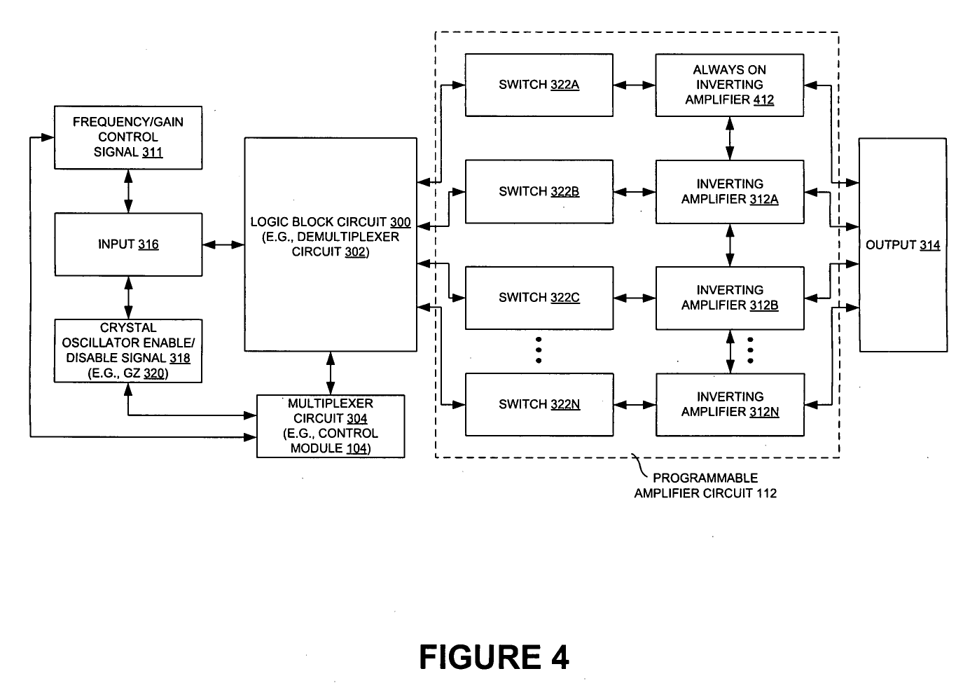

FIG. 4 is a system view illustrating a constant gain configuration for the integrated circuit through the switches that may keep one of an inverting amplifier always on, according to one embodiment. Particularly, FIG. 4 illustrates the programmable amplifier circuit 112, the logic block circuit 300 (e.g., the demultiplexer circuit 302), the multiplexer circuit 304 (e.g., the control module 104), the frequency/gain control signal 311, the always inverting amplifier 412A-N, the output 314, the input 316, the crystal oscillator enable/disable signal 318 (e.g., the GZ 320), and the switch 322A-N, according to one embodiment.

The always on inverting amplifier 412A-N may be the inverting amplifier 312A-N which may be always in on-state (e.g., providing a gain required when the circuit is stable) for generating sustained (e.g., the stable condition of the circuit) oscillations.

In example embodiment, the logic block circuit 300 (e.g., the demultiplexer circuit 302) may be coupled with the multiplexer circuit 304 (e.g., the control module 104), and the programmable amplifier circuit 112. The programmable amplifier circuit 112 may include the switches 322A-N that may be coupled with the always inverting amplifier, and the another inverting amplifiers 312B-N in parallel to determine the gain and/or the bandwidth value of the output signal 314. The inverting amplifiers 312A-N coupled with switches 322A-N may determine the gain and/or the bandwidth value of the output signal. 314. The input 316 obtained from the crystal oscillator enable/disable signal 318(e.g., the GZ 320 signal) and may be controlled by frequency/gain control signal 311 associated with multiplexer circuit 304 (e.g., the control module 104) that may be coupled with logic block circuit (e.g., the logic block circuit 300 (e.g., the demultiplexer circuit 302). Once the oscillations have started, the control of the programmable amplifier circuit 112 may be changed to lower the power consumption of the circuit (e.g., the integrated circuit 100).

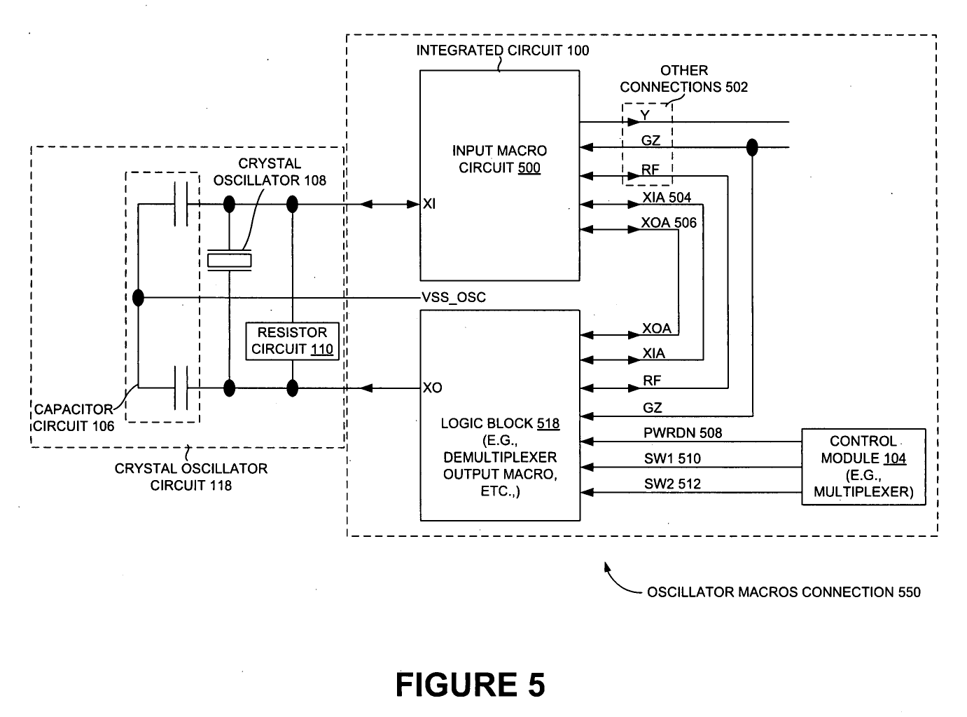

FIG. 5 is a schematic view illustrating an oscillator macros connection 550, according to one embodiment. Particularly, FIG. 5 illustrates the integrated circuit 100, the control module 104 (e.g., the multiplexer), the capacitor circuit 106, the crystal oscillator circuit 118, the resistor circuit 110, an input macro circuit 500, an other connections 502, a logic block 518 (e.g., the demultiplexer output macro, etc.), XIA 504, XOA 506, PWRDN 508, SW1 510, and SW2 512, according to one embodiment.

The other connections 502 (e.g., Y, GZ (the oscillator enable/disable signal), RF, etc.) may be the oscillator macro connections which may be connected to the logic block 518 and the input macro. The XIA 504 may be the input signal of the crystal oscillator circuit 118 which may communicate with the input macro circuit 500 and/or the logic block 518. The XOA 506 may be the output signal of the crystal oscillator circuit 118 which may communicate with input macro circuit 500 and/or logic block 518.

The PWRDN 508 signal may be a signal line that may be required by the logic block to perform some miscellaneous function (e.g., to achieve significant power savings without losing any data or operation context). The SW1 510 may be the signal line (e.g., may be used to add and/or remove additional frequency/gain) that may be required to determine the gain (e.g., change in the amplitude) in a specified frequency. The SW1 510 (e.g., a frequency/gain select pin) may be the signal line (e.g., may be used to add and/or remove additional frequency/gain) that may be required to determine the gain (e.g., change in the amplitude) in a specified frequency. The input macro circuit 500 may be a receiver circuit with hysteresis (e.g., Schmitt trigger, etc.) that may reject noise (e.g., an unwanted signal, etc.). The logic block 518 (e.g., demultiplexer, output macro, etc.) may be the inverting amplifier that may invert the signal at its input.

In example embodiment, the crystal oscillator circuit 118 may include the crystal, the capacitor circuit 106, and/or the resistor circuit 110 that may be coupled with integrated circuit 100. The integrated circuit 100 may include the input macro circuit 500 and the logic block 518 (e.g., the demultiplexer output macro etc.). The input macro circuit 500 may be coupled with the other connections 502, the XIA 504, and the XOA 506 (e.g., oscillator input-output connections) that may be connected to the logic block 518 (e.g., demultiplexer output macro, etc.). The PWRDN 508, the SW1 510, and the SW2 512 may be the connections from the control module 104 (e.g., the multiplexer) to the logic block 518 (e.g., the demultiplexer output macro, etc.).

In one embodiment, the input macro circuit 500 may determine the specified frequency value of the crystal oscillator circuit 118. The input macro circuit 500 may be configured to determine the specified frequency value of the crystal oscillator circuit 118 according to the command signal of the control module 104.

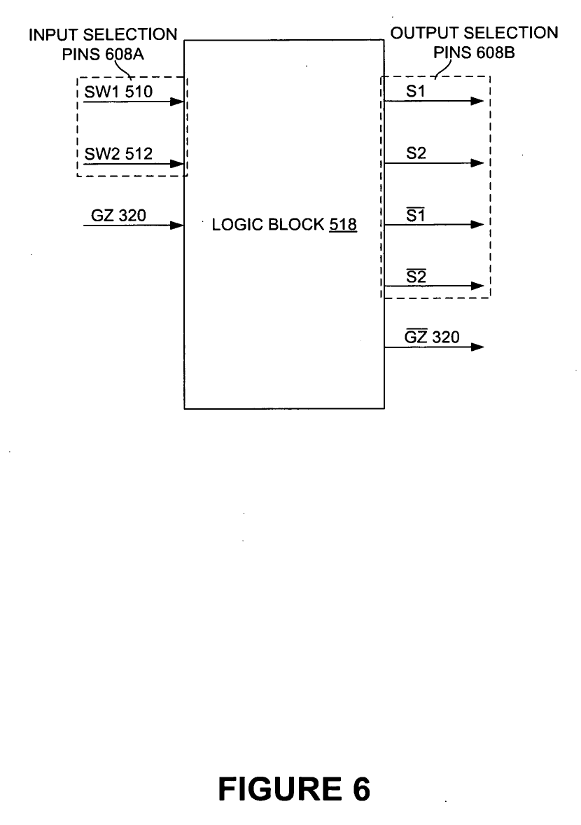

FIG. 6 is a block diagram illustrating the logic block 518 that includes a selection pins (e.g., the input selection pins 608A, and the output selection pins 608B of FIG. 6), according to one embodiment. Particularly, FIG. 6 illustrates the logic block 518, the GZ 320, the SW1 510, the SW2 512, the input selection pins 608A, the output selection pins 608B, the GZ 320, and the inverse GZ 322, according to one embodiment.

In example embodiment, the logic block 518 may be coupled with the input selection pins 608A (e.g., SW1 510, SW2 512) and the output selection pins 608B (e.g., St, S2, complement of S1 and/or complement of S2). The GZ 320 may be an oscillator enable/disable signal that may be connected to the logic block 518. The inverse GZ 322 may be a inverse signal of the input signal GZ 320

In one embodiment, the selection pins (e.g., may be the input selection pins 608A, and the output selection pins 608B of FIG. 6) may be coupled to the logic block circuit 300 with both the control module 104 and the programmable power amplifier. The control module 104 may determine a logic state of certain ones of the selection pins. The selection pins may be used to couple the logic block circuit with both the control module 104 and the programmable power amplifier with the selection pins. The logic state of the selection pin may be determined.

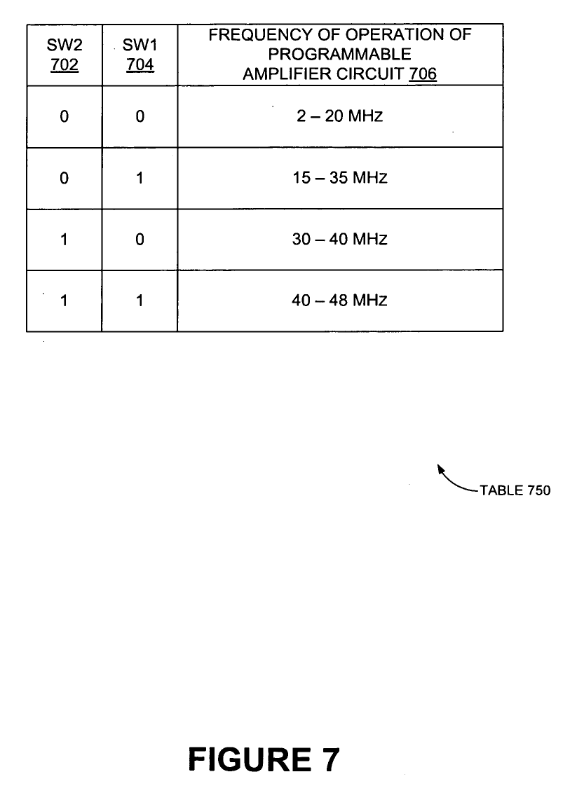

FIG. 7 is a table view illustrating a truth table of configuration of switches, according to one embodiment. Particularly, FIG. 7 illustrates a SW2 field 702, a SW1 field 704, and a freq of operation of programmable amplifier circuit field 706, according to one embodiment.

The SW2 field 702 may be an input logic (e.g., high, low) which may be given to logic block 518. The SW2 field 702 may be an input logic (e.g., high, low) which may be given to the logic block 518. The Freq of operation of programmable amplifier circuit field 706 may represent output frequencies obtained from logic block 518.

In example embodiment, the SW2 field 702 may illustrate various input logic values (e.g., 0, 1). The SW1 field 704 may also illustrate various input logic values (e.g., 0, 1). The Freq of operation of programmable amplifier circuit field 706 may illustrate various output frequencies (e.g., 2-20 MHz, 15-35 MHz, 30-40 MHz, and 40-48 MHz). When the configuration of SW1 and SW2 are low (e.g., 0) the range of operation of the programmable amplifier circuit field 706 may be 2-20 MHz. When the configuration of SW1 is high (e.g., 1) and SW2 is low (e.g., 0) the range of operation of the programmable amplifier circuit field 706 may be 15-35 MHz. When the configuration of SW1 is low (e.g., 0) and SW2 is high (e.g., 1) the range of operation of the programmable amplifier circuit field 706 may be 30-40 MHz. When the configuration of SW1 is high (e.g., 1) and SW2 is high (e.g., 1) the range of operation of the programmable amplifier circuit field 706 may be 40-48 MHz.

FIG. 8 is a diagrammatic view illustrating the programmable inverting amplifiers 800 coupled with on-state inverting amplifier 802, according to one embodiment. Particularly, FIG. 8 illustrates an on-state inverting amplifier 802, a p-type arm 804, and an n-type arm 806, according to one embodiment.

The on-state inverting amplifier 802 may be the inverting amplifier which may include transistors (e.g., PMOS, NMOS, etc.) which may provide required gain (e.g., when the circuit is stable, etc.) depending upon the specified frequency. The p-type arm 804 may be a p-type semiconductor device (e.g., PMOS transistor, etc.) which may be used when there is requirement of extra gain (e.g., may be during switching on the IC). The n-type arm 806 may be an n-type semiconductor device (e.g., PMOS transistor, etc.) which may be used in parallel to its p-type arm (e.g., MP3 for MN4 and M2for MN3) for providing the required gain for the IC.

In example embodiment, the on-state inverting amplifier 802 may include p-type arm 804 and n-type arm 806 that may be coupled with inputs (e.g., the GZ, the XI, the complement of GZ, etc.). The XI may be the input value to the transistors (e.g., to the MP4, MN1, etc.) to provide output at the XO for a specified frequency value.

In one embodiment, the programmable amplifier circuit 112 may include the on-state inverting amplifier 802 coupled in parallel with the programmable inverting amplifiers 800 coupled in parallel. The on-state inverting amplifier 802 may include the p-type arm 804 comprised of a pair of p-type semiconductors and a voltage source coupled in series and an n-type arm (e.g., the n-type arm 806 of FIG. 8) comprised of a pair of n-type semiconductors and a ground (e.g., the ground 220 of FIG. 2) coupled in series. The on-state inverting amplifier 802 may be coupled with the signal transmission line from the crystal oscillator circuit 118, the output signal transmission line and the control module 104.

The on-state inverting amplifier 802 may be the active state of operation if the crystal oscillator 108 may be in the active state of operation. The on-state inverting amplifier 802 may be the inactive state of operation if the crystal oscillator 108 is in the inactive state of operation. The on-state inverting amplifier 802 with the p-type arm 804 may include the pair of p-type semiconductors and the voltage source coupled in series and the n-type arm 806 may include the pair of n-type semiconductors and the ground 220 coupled in series may be configured. The on-state inverting amplifier 802 may be coupled with the signal transmission line from the crystal oscillator circuit 118, the output signal transmission line and the control module 104. The on-state inverting amplifier 802 may be configured in the active state of operation if the crystal oscillator circuit 118 is in the active state of operation. The on-state inverting amplifier 802 may be configuring in the inactive state of operation if the crystal oscillator circuit 118 is in the inactive state of operation. The p-type arm 804 may be coupled with the output the output signal 314 of the programmable amplifier circuit 112. The n-type arm 806 may be coupled with the signal transmission line from the crystal oscillator 108.

FIG. 9 is a diagrammatic view illustrating a different configuration of a programmable inverting amplifier 900 coupled with the on-state inverting amplifier, according to one embodiment. Particularly, FIG. 9 illustrates an on-state inverting amplifier 902, a p-type arm 904, and an n-type arm 906, according to one embodiment.

The on-state inverting amplifier 902 may be another inverting amplifier which may contain transistors (e.g., PMOS, NMOS, etc.) which may provide required gain (e.g., voltage, frequency, etc.) depending upon the specified frequency. The p-type arm 904 may be a p-type semiconductor device (e.g., PMOS transistor, etc.) which may be a part of on-state inverting amplifier 802. The n-type arm 906 may be an n-type semiconductor device (e.g., PMOS transistor, etc.) which may be a part of on-state inverting amplifier.

In example embodiment, on-state inverting amplifier 902 may include p-type arm 804 and n-type arm 806 that may be coupled with inputs (e.g., the GZ, the XI, the complement of GZ, etc.). The XI may be the input value coupled with transistors (e.g., the MP4, the MN1, etc.) to provide output at the XO for the specified frequency value

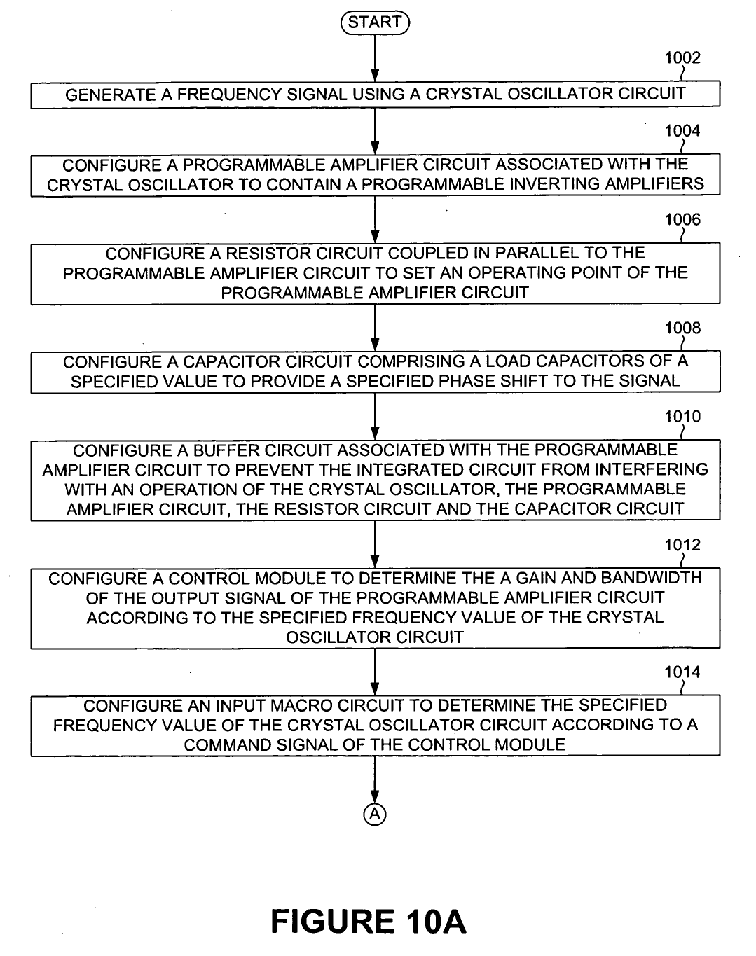

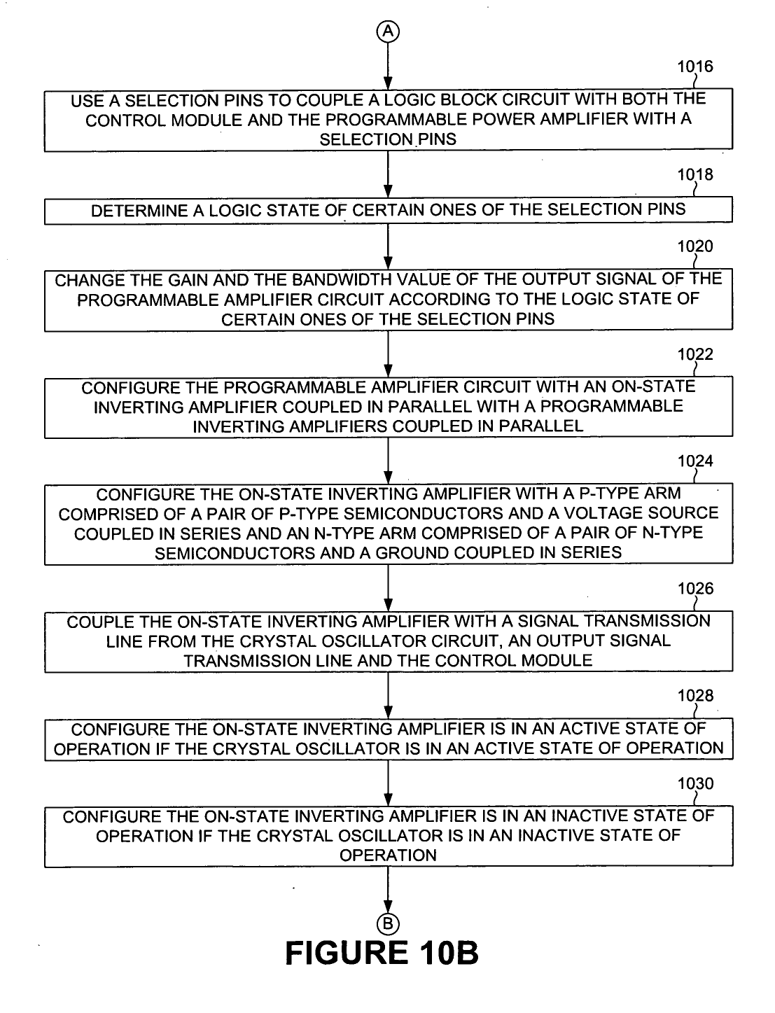

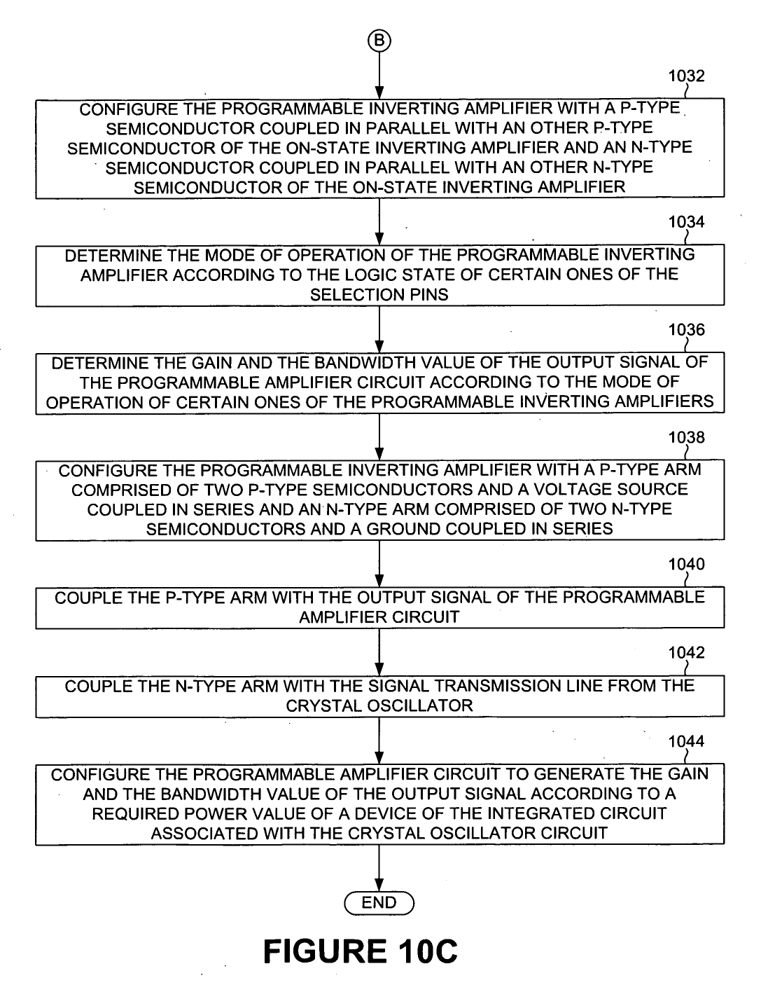

FIG. 10A is a process flow of generating a frequency signal using a crystal oscillator, according to one embodiment. In operation 1002, a frequency signal (e.g., the frequency/gain control signal 311 of FIG. 3) may be generated using a crystal oscillator circuit (e.g., the crystal oscillator circuit 118 of FIG. 1). In operation 1004, a programmable amplifier circuit (e.g., the programmable amplifier circuit 112 of FIG. 1) associated with the crystal oscillator circuit 118 may be configured to include programmable inverting amplifiers. The programmable inverting amplifiers may operate to change the gain and/or the bandwidth value of an output signal (e.g., the output signal 216 of FIG. 2) of the programmable amplifier circuit 112 according to a frequency value of a crystal oscillator circuit (e.g., the crystal oscillator circuit 118 of FIG. 1).

In operation 1006, a resistor circuit (e.g., the resistor circuit 110 of FIG. 1) coupled in parallel to the programmable amplifier circuit 112 may be configured to set an operating point of the programmable amplifier circuit 112. In operation 1008, a capacitor circuit (e.g., the capacitor circuit 106 of FIG. 1) including load capacitors (e.g., the load capacitor 206A-B etc.) of a specified value may be configured to provide a specified phase shift to a signal (e.g., the input signal 212 of FIG. 2). In operation 1010, a buffer circuit (e.g., the buffer circuit 114 of FIG. 1) (e.g., I/P buffer etc.) associated with the programmable amplifier circuit 112 may be configured to prevent the integrated circuit 100 from interfering with an operation of the crystal oscillator 108, the programmable amplifier circuit 112, the resistor circuit 110 and/or the capacitor circuit 106.

In operation 1012, a control module (e.g., the control module 104 of FIG. 1) may be configured to determine the gain and/or the bandwidth value of the output signal 216 of the programmable amplifier circuit 112 according to a specified frequency value of the crystal oscillator circuit 118. In operation 1014, an input macro circuit (e.g. the input macro circuit 500 of FIG. 5) may be configured to determine the specified frequency value of the crystal oscillator circuit 118 according to a command signal of the control module 104.

FIG. 10B is a continuation of process flow of FIG. 10A, illustrating additional operations, according to one embodiment. In operation 1016, a selection pins (e.g., the input selection pins 608A, and the output selection pins 608B of FIG. 6) may be used to couple a logic block circuit (e.g., the logic block circuit 300 of FIG. 3) (e.g., demultiplexer circuit 302, etc.) with both the control module 104 and a programmable power amplifier with the selection pins. In operation 1018, a logic state of a selection pins may be determined. In operation 1020, the gain and/or the bandwidth value of the output signal 216 of the programmable amplifier circuit 112 may be changed according to the logic state of the selection pins.

In operation 1022, the programmable amplifier circuit 112 may be configured with an on-state inverting amplifier (e.g., the on-state inverting amplifier 802 of FIG. 8) coupled in parallel with the programmable inverting amplifiers coupled in parallel. In operation 1024, the on-state inverting amplifier 802 may be configured with a p-type arm (e.g., the p-type arm 804 of FIG. 8) consisting a pair of p-type semiconductors and a voltage source coupled in series and an n-type arm (e.g., the n-type arm 806 of FIG. 8) consisting a pair of n-type semiconductors and a ground (e.g., the ground 220 of FIG. 2) coupled in series. In operation 1026, the on-state inverting amplifier 802 may be coupled with a signal transmission line from the crystal oscillator circuit 118, an output signal (e.g., the output signal 216 of FIG. 2) transmission line and the control module 104. In operation 1028, the on-state inverting amplifier 802 may be configured to an active state of operation if the crystal oscillator circuit 118 may be in the active state of operation. In operation 1030, the on-state inverting amplifier 802 may be configured to an inactive state of operation if the crystal oscillator circuit 118 may be in the inactive state of operation.

FIG. 10C is a continuation of process flow of FIG. 10B, illustrating additional operations, according to one embodiment. In operation 1032, a programmable inverting amplifier (e.g., the programmable inverting amplifier 800 of FIG. 8) may be configured with a p-type semiconductor coupled in parallel with an other p-type semiconductor of the on-state inverting amplifier 802 and an n-type semiconductor coupled in parallel with an other n-type semiconductor of the on-state inverting amplifier 802. In operation 1034, a mode of operation of the programmable inverting amplifier 800 may be determined according to the logic state of the selection pins. In operation 1036, the gain and/or the bandwidth value of the output signal 216 of the programmable amplifier circuit 112 may be determined according to the mode of operation of the programmable inverting amplifiers (e.g., the programmable inverting amplifier 800 etc.).

In operation 1038, the programmable inverting amplifier 800 may be configured with a p-type arm (e.g., the p-type arm 804 of FIG. 8) including two p-type semiconductors and the voltage source coupled in series and an n-type arm (e.g., the n-type arm 806 of FIG. 8) including two n-type semiconductors and the ground 220 coupled in series. In operation 1040, the p-type arm 804 may be coupled with the output signal 216 of the programmable amplifier circuit 112. In operation 1042, the n-type arm 806 may be coupled with the signal transmission line from the crystal oscillator 108. In operation 1044, the programmable amplifier circuit 112 may be configured to generate the gain and/or the bandwidth value of the output signal 216 according to a required power value of a device of the integrated circuit 100 associated with the crystal oscillator circuit 118.

Although the present embodiments have been described with reference to specific example embodiments, it will be evident that various modifications and changes may be made to these embodiments without departing from the broader spirit and scope of the various embodiments. For example, the various devices, modules, analyzers, generators, etc. described herein may be enabled and operated using hardware circuitry (e.g., CMOS based logic circuitry), firmware, software and/or any combination of hardware, firmware, and/or software (e.g., embodied in a machine readable medium). For example, the various electrical structure and methods may be embodied using transistors, logic gates, and electrical circuits (e.g., application specific integrated (ASIC) circuitry and/or in Digital Signal Processor (DSP) circuitry).

Particularly, the control module 104, and the other modules 116 of FIG. 1-10 may be enabled using software and/or using transistors, logic gates, and electrical circuits (e.g., application specific integrated ASIC circuitry) such as the integrated circuit 100, the selectable gain circuit 102, the capacitor circuit 106, the resistor circuit 110, the programmable amplifier circuit 112, the buffer circuit 114, the buffer circuit 214 (e.g., I/P buffer 218), the resistor circuit 210, the logic block circuit 300 (e.g., the demultiplexer circuit 302), the multiplexer circuit 304, the input macro circuit 500, and other circuits.

In addition, it will be appreciated that the various operations, processes, and methods disclosed herein may be embodied in a machine-readable medium and/or a machine accessible medium compatible with a data processing system (e.g., a computer system), and may be performed in any order (e.g., including using means for achieving the various operations). Accordingly, the specification and drawings are to be regarded in an illustrative rather than a restrictive sense.

What is claimed is:

1. A system comprising:
a crystal oscillator circuit to generate a signal with a specified frequency value; and
a programmable amplifier circuit containing a plurality of programmable inverting amplifiers, and wherein certain ones of a plurality of inverting amplifiers are operated to change at least one of a gain value and a bandwidth value of the signal according to the specified frequency value of the crystal oscillator circuit.

2. The system of claim 1:
further comprising a resistor circuit coupled in parallel to the programmable amplifier circuit to set an operating point of the programmable amplifier circuit;
further comprising a capacitor circuit comprising a plurality of load capacitors of a specified value to provide a specified phase shift to the signal; and
further comprising a buffer circuit associated with the programmable amplifier circuit to prevent an integrated circuit from interfering with an operation of at least one of the crystal oscillator circuit, the programmable amplifier circuit, the resistor circuit and the capacitor circuit.

3. The system of claim 1, further comprising:
a control module to determine at least one of the gain value and the bandwidth value of an output signal of the programmable amplifier circuit according to the specified frequency value of the crystal oscillator circuit; and
an input macro circuit to determine the specified frequency value of the crystal oscillator circuit.

4. The system of claim 3:
further comprising a plurality of selection pins to couple a logic block circuit with both the control module and a programmable power amplifier;
wherein the control module determines a logic state of certain ones of the plurality of a selection pins; and
wherein the logic block circuit determines at least one of the gain value and the bandwidth value of the output signal of the programmable amplifier circuit according to the logic state of certain ones of the plurality of selection pins.

5. The system of claim 4:
wherein the programmable amplifier circuit is comprised of an on-state inverting amplifier coupled in parallel with the plurality of programmable inverting amplifiers coupled in parallel;
wherein the on-state inverting amplifier is comprised a p-type arm comprised of a pair of p-type semiconductors and a voltage source coupled in series and an n-type arm comprised of a pair of n-type semiconductors and a ground coupled in series;
wherein the on-state inverting amplifier is coupled with a signal transmission line from the crystal oscillator circuit, an output signal transmission line and the control module;
wherein the on-state inverting amplifier is in an active state of operation if a crystal oscillator is in the active state of operation; and
wherein the on-state inverting amplifier is in an inactive state of operation if the crystal oscillator is in the inactive state of operation.

6. The system of claim 5:
wherein a programmable inverting amplifier is comprised of a p-type semiconductor coupled in parallel with an other p-type semiconductor of the on-state inverting amplifier and an n-type semiconductor coupled in parallel with an other n-type semiconductor of the on-state inverting amplifier;
wherein a mode of operation of the programmable inverting amplifier is determined by the logic block circuit according to the logic state of certain ones of the plurality of the selection pins; and
wherein the logic block circuit determines at least one of the gain value and the bandwidth of the output signal of the programmable amplifier circuit according to the mode of operation of certain ones of the plurality of programmable inverting amplifiers.

7. The system of claim 5:
wherein the programmable inverting amplifier is comprised a p-type arm comprised of two p-type semiconductors and the voltage source coupled in series and an n-type arm comprised of two n-type semiconductors and the ground coupled in series; and
wherein the p-type arm is coupled with the output of the programmable amplifier circuit and the n-type arm is coupled with the signal transmission line from the crystal oscillator circuit.

8. The system of claim 7 wherein the resistor circuit is located within the programmable amplifier circuit.

9. The system of claim 1 wherein the programmable amplifier circuit generates the amplitude value of the output signal according to a required power value of a device of the integrated circuit associated with the programmable amplifier circuit.

10. A method comprising:
generating a frequency signal using a crystal oscillator circuit; and
configuring a programmable amplifier circuit associated with the crystal oscillator circuit to contain a plurality of programmable inverting amplifiers, and wherein certain ones of the plurality of programmable inverting amplifiers are operated to change at least one of a gain value and a bandwidth value of an output signal of the programmable amplifier circuit according a frequency value of the crystal oscillator circuit.

11. The method of claim 10 further comprising:
configuring a resistor circuit coupled in parallel to the programmable amplifier circuit to set an operating point of the programmable amplifier circuit;
configuring a capacitor circuit comprising a plurality of load capacitors of a specified value to provide a specified phase shift to a signal; and
configuring a buffer circuit associated with the programmable amplifier circuit to prevent the integrated circuit from interfering with an operation of at least one of the crystal oscillator circuit, the programmable amplifier circuit, the resistor circuit and the capacitor circuit.

12. The method of claim 11 further comprising:
configuring a control module to determine at least one of the gain value and the bandwidth value of the output signal of the programmable amplifier circuit according to a specified frequency value of the crystal oscillator circuit; and
configuring an input macro circuit to determine the specified frequency value of the crystal oscillator circuit according to a command signal of the control module.

13. The method of claim 10 further comprising:
using a plurality of selection pins to couple a logic block circuit with both the control module and a programmable power amplifier with the plurality of selection pins;
using the control module to decrease a power consumption value of an integrated circuit associated with the programmable power amplifier;
determining a logic state of certain ones of the plurality of a selection pins; and
changing at least one of the gain value and the bandwidth value of the output signal of the programmable amplifier circuit according to the logic state of certain ones of the plurality of selection pins.

14. The method of claim 13 further comprising:
configuring the programmable amplifier circuit with an on-state inverting amplifier coupled in parallel with the plurality of programmable inverting amplifiers coupled in parallel;
configuring the on-state inverting amplifier with a p-type arm comprised of a pair of p-type semiconductors and a voltage source coupled in series and an n-type arm comprised of a pair of n-type semiconductors and a ground coupled in series;
coupling the on-state inverting amplifier with a signal transmission line from the crystal oscillator circuit, an output signal transmission line and the control module;
configuring the on-state inverting amplifier is in an active state of operation if the crystal oscillator circuit to be in the active state of operation; and
configuring the on-state inverting amplifier is in an inactive state of operation if the crystal oscillator circuit to be in the inactive state of operation

15. The method of claim 14 further comprising:
configuring a programmable inverting amplifier with a p-type semiconductor coupled in parallel with an other p-type semiconductor of the on-state inverting amplifier and an n-type semiconductor coupled in parallel with an other n-type semiconductor of the on-state inverting amplifier;
determining a mode of operation of the programmable inverting amplifier according to the logic state of certain ones of the plurality of the selection pins; and
determining at least one of the gain value and bandwidth value of the output signal of the programmable amplifier circuit according to the mode of operation of certain ones of the plurality of programmable inverting amplifiers.

16. The method of claim 14 further comprising:
configuring the programmable inverting amplifier with a p-type arm comprised of two p-type semiconductors and the voltage source coupled in series and an n-type arm comprised of two n-type semiconductors and the ground coupled in series;
coupling the p-type arm with the output the output signal of the programmable amplifier circuit; and
coupling the n-type arm with the signal transmission line from the crystal oscillator circuit.

17. The method of claim 15 further comprising configuring the programmable amplifier circuit to generate at least one of the gain value and the bandwidth value of the output signal according to a required power value of a device of the integrated circuit associated with the crystal oscillator circuit.

18. A system comprising:
a vibrating crystal of a piezoelectric material to create an electrical signal;
an amplifier to change a gain value of the electrical signal and configured with a plurality of inverting amplifier arms in parallel comprising a programmable inverting amplifier coupled with a switch; and
an output control module coupled to the amplifier to control the operation of certain ones of plurality of amplifier arms according to a frequency of the electrical signal of the vibrating crystal.

19. The system of claim 18 wherein a control module activates certain ones of the plurality of amplifier arms according to a power requirement of a device associated with the vibrating crystal.

20. The system of claim 19 further comprising at least one capacitor to provide a specified phase shift to the electrical signal.
